(19) United States
(12) Patent Application Publication
(10) Pub. No.: US 2005/0213686 A1
(43) Pub. Date: Sep. 29, 2005

(54) Reduced complexity transmit spatial waterpouring technique for multiple-input, multiple-output communication systems

(75) Inventors: David J. Love, Garland, TX (US); Srinath Hosur, Plano, TX (US); Anuj Batra, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 10/810,764

(22) Filed: Mar. 26, 2004

(51) Int. Cl. H04L 27/20; H03H 7/30

(52) U.S. Cl. 375/299; 375/298

(57) ABSTRACT

A waterpouring system and method for use with a multiple-input, multiple-output (MIMO) transmitter. In one embodiment, the waterpouring system includes an encoding decision subsystem that selects a constellation combination based on gains in channels of the MIMO transmitter, and a vector modulator subsystem, coupled to the encoding decision system, that modulates a fixed number of bits in a bitstream with the constellation combination to generate a symbol vector. The waterpouring system also includes a normalization and precoding subsystem, coupled to the vector modulator subsystem, that weights the symbol vector based on the gains to yield a weighted symbol vector and distributes the weighted symbol vector among the channels.

### TECHNICAL FIELD OF THE INVENTION

The present invention is directed, in general, to multiple-input, multiple-output (MIMO) communication systems and, more specifically, to a reduced complexity transmit spatial waterpouring technique for MIMO communication systems.

### BACKGROUND OF THE INVENTION

Multiple-input multiple output (MIMO) communication systems have been shown to provide improvements in capacity and reliability over single-input single-output (SISO) communication systems. MIMO communication systems commonly employ a block structure wherein a MIMO transmitter, actually a collection of single-dimension transmitters, sends a vector of symbol information. This symbol vector may represent one or more coded or uncoded SISO data symbols. The transmitted signal propagates through the channel and is received and processed by a MIMO receiver. The MIMO receiver can obtain multiple received signals corresponding to each transmitted symbol. The-performance of the entire communication system hinges on the ability of the receiver to find reliable estimates of the symbol vector that was transmitted.

For such MIMO communication systems, a receive signal may be written in the form

$${y}_{k} = {\sum }_{n} {H}_{n} {s}_{k - n} + v \qquad ( 1 )$$

where Hₙ is an Mr by Mt matrix of common gains, Sₖ is the Mₜ-dimensional symbol vector transmitted at time k and v is a Mᵣ-dimensional vector of additive noise. In narrowband wireless systems, where the symbol period is much larger than the RMS delay spread or in orthogonal frequency division multiplexing (OFDM) systems (for each frequency bin) where the inter-symbol interference is negligible due to the insertion of a cyclic prefix or a guard interval, the channel from each transmit antenna to each receive antenna is often modeled as a single-tap complex gain. In this case, equation (1) simplifies to
yₖ=Hsₖ+v, (2)
where H is now an Mᵣ by Mₜ matrix of complex numbers and Hsₖ is the matrix product of H and s. Each of the symbols within the symbol vector sₖ may be chosen from any constellation. For example, this may mean that one symbol uses 16-QAM while another uses 4-QAM.

In communication systems using frequency division duplexing or time division duplexing where the time slots are longer than the channel coherence time, reliable channel information will not be available at the transmitter without some sort of feedback. Unfortunately, feedback systems are often infeasible for communication systems because of the reduction in bit rate typically involved. One approach to vector signaling is to force each symbol in sₖ to be chosen from the same constellation. This type of system (often called V-BLAST) when used with MIMO wireless communication systems, sends each symbol with the vector sₖ from different transmitters. The advantages of MIMO communication systems using this type of technique are that the system is relatively straightforward to implement and, generally, channel information is not needed at the transmitter.

It is well known within communication engineering that techniques incorporating channel information generally outperform techniques that make no use of channel information. For vector channels (i.e., single-input multiple-output or multiple-input single-output communication systems) channel state information has been used to improve performance by using combining or beamforming. Combining systems employ receive antenna weighting at each antenna to yield a receive signal
yₖ=z*Hsₖ+z*v, (3)
where a receive antenna i weights its received signal by zᵢ*, z=[z₁ z₂ . . . z_{Mr}]^{T}, and H is a length Mᵣ column vector. The operator “*” denotes the matrix conjugate transpose operation and the operator “T” denotes matrix transposition.

Beamforming systems employ transmit antenna weightings. In a beamforming system, the received signal may be represented by
yₖ=Hwsₖ+v, (4)
where tramsmit antenna i weights its received signal by wᵢ, w=[w₁ w₂ . . . w_{Mr}]^{T}, and H is a length Mₜ row vector. When the channel H is a matrix, combining and beamforming can be combined together to yield a receive signal vector of
yₖ=z*Hwsₖ+z*v (5)
These systems achieve good performance, but are not true vector signaling systems since the transmitter is only sending a one-dimensional symbol at each burst.

Current MIMO communication systems typically perform below their possible capacity. To improve performance, “waterpouring” techniques have been proposed previously for MIMO communication systems. In waterpouring, the maximum supported bit rate for each subchannel is calculated (each subchannel containing more or less noise that affects the bit rate). The transmitter sends at the maximum possible supported bit rate, such that the combined signal and noise power for each channel is nearly equal (hence the name “waterpouring”).

Current waterpouring techniques tend to be extremely computationally complex from the viewpoint of calculating the supported bit rate. For systems where the channel coherence time is low, the supported bit rates would have to be computed often thus adding significant computational overhead. Accordingly, what is needed in the art is a way to provide a waterpouring technique of reduced complexity that allows gain improvements for MIMO communication systems.

### SUMMARY OF THE INVENTION

To address the above-discussed deficiencies of the prior art, the present invention is directed to a waterpouring system for use with a multiple-input, multiple-output (MIMO) transmitter. In one embodiment, the waterpouring system includes an encoding decision subsystem configured to select a constellation combination based on gains in channels of the MIMO transmitter, and a vector modulator subsystem, coupled to the encoding decision subsystem, configured to modulate a fixed number of bits in a bitstream with the constellation combination to generate a symbol vector. The waterpouring system also includes a normalization and precoding subsystem, coupled to the vector modulator subsystem, configured to weight the symbol vector based on the gains to yield a weighted symbol vector and distribute the weighted symbol vector among the channels.

In another aspect, the present invention provides a waterpouring method for use with a MIMO transmitter. The method includes selecting a constellation combination based on gains in channels of the MIMO transmitter and modulating a fixed number of bits in a bitstream with the constellation combination to generate a symbol vector. The method also includes weighting the symbol vector based on the gains to yield a weighted symbol vector and distributing the weighted symbol vector among the channels.

In yet another aspect, the present invention is directed to a MIMO transmitter employing an input bitstream. The MIMO transmitter includes a plurality of transmit channels and a waterpouring system. The waterpouring system has an encoding decision block that selects a constellation combination based on gains in channels of the MIMO transmitter and a vector modulator, coupled to the encoding decision block, that modulates a fixed number of bits in the input bitstream with the constellation combination to generate a symbol vector. The waterpouring system also has normalization and preceding circuitry, coupled to the vector modulator, that weights the symbol vector based on the gains to yield a weighted symbol vector and distributes the weighted symbol vector among the channels.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention in its broadest form.

### BRIEF DESCRIPTION OF THE DRAWINGS

For a more complete understanding of the present invention, reference is now made to the following descriptions taken in conjunction with the accompanying drawings, in which:

FIG. 1 illustrates an embodiment of a MIMO transmitter constructed according to the principles of the present invention;

FIG. 2 illustrates a block diagram of an embodiment of a waterpouring system for a MIMO transmitter constructed according to the principles of the present invention;

FIG. 3 illustrates a graph showing a bit error rate (BER) comparison between an embodiment of a constant rate waterpouring system and method constructed according to the principles of the present invention and V-BLAST while employing a two by two MIMO communication system having Rayleigh fading; and

FIG. 4 illustrates a graph showing a bit error rate (BER) comparison between an embodiment of a constant rate waterpouring system and method constructed according to the principles of the present invention and V-BLAST while employing a two by two MIMO communication system having equal energy Rayleigh fading paths.

### DETAILED DESCRIPTION

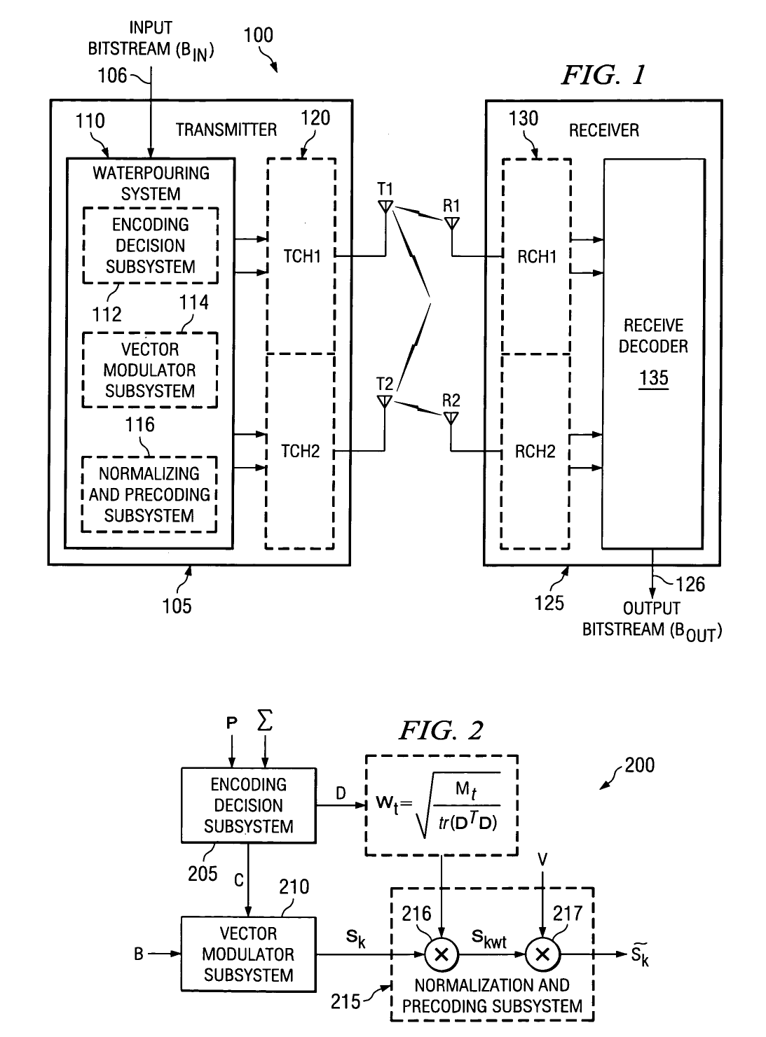

Referring initially to FIG. 1, illustrated is an embodiment of a two by two MIMO communication system, generally designated 100, constructed according to the principles of the present invention. The MIMO communication system 100 includes a MIMO transmitter 105 and a MIMO receiver 125. The MIMO transmitter 105 includes a transmit input 106 having an input bitstream Bin, a waterpouring system 110 and a transmit system 120 having first and second transmit channels TCH1, TCH2 that couple first and second transmit substreams TS1, TS2 to first and second transmit antennas T1, T2, respectively. The MIMO receiver 125 includes first and second receive antennas R1, R2, that respectively couple first and second receive substreams RS1, RS2 to first and second receive channels RCH1, RCH2 of a receive system 130 and a receive decoder 135 having a receive output 126 that provides an output bitstream Bout.

The illustrated embodiment of FIG. 1 represents only one example of numerous MIMO communication systems that may employ the principles of the present invention. Additionally, in the illustrated and alternative embodiments of the present invention, the MIMO transmitter 105 may form a part of a selected one of a narrowband wireless communication system employing multiple antennas, a broadband communication system employing OFDM, a time division multiple access (TDMA) communication system and a multiuser communication system. Those skilled in the art will perceive, however, that the present invention can be applied to other conventional and later-developed MIMO communication systems.

The first and second transmit channels TCH1, TCH2 include the frequency tuning, modulation and power amplification circuitry required to condition and transmit the first and second transmit substreams TS1, TS2. The first and second receive channels RCH1, RCH2 contain the required capture, detection and recovery circuitry to allow processing of the first and second receive substreams RS1, RS2 into a symbol configuration that may be employed by the receive decoder 135. The receive decoder 135 decodes the first and second receive streams RS1, RS2 into the output bitstream Bout that is representative of the input bitstream Bin.

The waterpouring system 110 converts the input bitstream Bin into a stream of vector symbols (i.e., a complex representation having both amplitude and phase components) and provides an output to the transmit system 120. The waterpouring system 110 includes an encoding decision subsystem 112, a vector modulator subsystem 114 and a normalization and preceding subsystem 116. The encoding decision subsystem 112 selects a constellation combination based on gains in the first and second transmit channels TCH1, TCH2. The vector modulator subsystem 114 is coupled to the encoding decision subsystem 112 and modulates a fixed number of bits in the input bitstream Bin with the constellation combination to generate a symbol vector. The normalization and precoding subsystem 116 is coupled to the vector modulator subsystem 114 and weights the symbol vector based on the gains to yield a weighted vector symbol. The weighted vector symbol is distributed among the first and second transmit channels TCH1, TCH2.

The waterpouring system 110 employs a reduced complexity preceding and constant rate waterpouring method that allows a fixed number of bits to be transmitted. This fixed number of bits may be accommodated by a single vector symbol or a plurality of vector symbols. In contrast, a classical waterpouring system would attempt to pour a maximum number of achievable bits per second on each of the first and second transmit channels TCH1, TCH2. The waterpouring system 110 may distribute the fixed number of bits in several ways between each of the first and second transmit substreams TS1, TS2. For example, in the waterpouring system 110, a fixed number of constellation combinations, which may be used to modulate the fixed number of bits, may be contained in a constellation set P.

In the illustrated embodiment, the two by two MIMO communication system 100 may send eight bits at each transmission. In the illustrated embodiment, the encoding decision subsystem 112 selects the constellation combination from the constellation set P constituted from at least one modulation technique selected from the group consisting of quadrature amplitude modulation and phase shift keying. Of course, other embodiments of the present invention may employ other current or future developed constellations or modulation techniques.

A first choice for the constellation set P may be to choose three constellation combinations, such as
P={{16-QAM,16-QAM}{64-QAM,4-QAM}{128-QAM, BPSK}}.
Alternatively, a second choice for the constellation set P may be to choose only a single constellation combination, such as
P={{64-QAM,4-QAM}}.
Since the complexity of the method typically increases as the number of different constellation combinations in the constellation set P increases, a designer may trade performance for complexity, as appropriate to an application.

For modulation use, a constellation combination may be chosen within the constellation set P based on a performance metric. For example, in the illustrated embodiment, the capacity of each subchannel may be computed and the maximum-rate subchannel constellation along with a corresponding gain chosen in order to meet a number of bits per transmission requirement. Additionally, a gain matrix may also be chosen such that the total transmission power remains the same.

Turning now to FIG. 2, illustrated is a block diagram of an embodiment of a waterpouring system for a MIMO transmitter, generally designated 200, constructed according to the principles of the present invention. The waterpouring system 200 includes an encoding decision subsystem 205 that receives a constellation set P and an input gain matrix Σ and provides a constellation combination C and a gain matrix D, which depend on the input gain matrix Σ and the allowable constellation set P. The waterpouring system 200 also includes a vector modulator subsystem 210 that receives the constellation combination C and a bitstream B and provides a symbol vector sₖ.

The waterpouring system 200 further includes a normalization and preceding subsystem 215 having a first multiplier 216 that multiplies the symbol vector sₖ and a weighting matrix Wₜ to provide a weighted symbol vector s_{kwt}. The normalization and precoding subsystem 215 also has a second multiplier 217 that multiplies the weighted symbol vector s_{kwt} and a preceding matrix V to provide a precoded weighted symbol vector \tilde{s}ₖ.

The encoding decision subsystem 205 is configured to select the constellation combination C based on the input gain matrix Σ and the allowable constellation set P. The vector modulator subsystem 210 is coupled to the encoding decision subsystem 205 and configured to modulate a fixed number of bits B_{BLOCK} in the bitstream B employing the constellation combination C to generate the symbol vector sₖ. The normalization and precoding subsystem 215 is coupled to the vector modulator subsystem 210 and configured to weight the symbol vector sₖ, based on the weighting matrix Wₜ. Precoding the weighted symbol vector s_{kwt} by the preceding matrix V distributes the precoded weighted symbol vector \tilde{s}ₖ among the channels of the MIMO transmitter.

A channel matrix H, representing the channel gains for the MIMO transmitter, may be represented by its singular value decomposition H=UΣV*, where U and V are unitary matrices and the input gain matrix Σ is an ordered, real diagonal matrix having its largest term in the (1,1) position. In the illustrated embodiment, the input gain matrix Σ is related to the channel gains by unitary matrices. After the bit stream is modulated into a symbol vector sₖ, it is multiplied by the weighting matrix Wₜ wherein

$${W}_{t} = \sqrt{\frac{{M}_{t}}{tr ( {D}^{T} D )}} \qquad ( 6 )$$

where tr(D^{T}D) denotes the trace of (D^{T}D) and D^{T} denotes the matrix transposition. This matrix weights the stream based on the substream channel gain. Precoding by the precoding matrix V may be interpreted as dividing the channels into its transmit substreams Mₜ since HV=UΣ.

The term

$$\sqrt{\frac{{M}_{t}}{tr ( {D}^{T} D )}} D ,$$

is a normalized term such that a total transmit energy may be expressed by the following:

$$\begin{matrix}E [ {\tilde{s}}_{k}^{*} {\tilde{s}}_{k} \vert ] = \frac{{M}_{t}}{tr ( {D}^{T} D )} tr ( E [ {Ds}_{k} {s}_{k}^{*} {D}^{T} \vert ] ) \\ = \frac{{M}_{t}}{tr ( {D}^{T} D )} tr ( DE [ {s}_{k} {s}_{k}^{*} \vert ] {D}^{T} ) \\ = \frac{{M}_{t}}{tr ( {D}^{T} D )} tr ( D \frac{{E}_{s}}{{M}_{t}} {D}^{T} ) \\ = \frac{{M}_{t} \frac{{E}_{s}}{{M}_{t}}}{tr ( {D}^{T} D )} tr ( {DD}^{T} ) \\ = {E}_{s} ,\end{matrix} \qquad ( 7 )$$

where Eₛ is the average symbol vector energy E[Sₖ*Sₖ|], and sₖ* denotes the matrix conjugate transpose.

In the illustrated embodiment, the precoded weighted symbol vector \tilde{s}ₖ has an energy that equals the total transmit energy of the MIMO transmitter. The weighted symbol vector s_{kwt} is precoded by V, which allocates each substream onto one of the transmit substreams associated with the total number of channels Mₜ, which are orthogonal right singular vectors of the matrix H. Thus, the total energy is spread among the various channels of the MIMO transmitter in accordance with the ability of its channels to accommodate the energy.

In one embodiment of the present invention, full knowledge of the channel may exist at the transmitter. In an alternative embodiment, a knowledge of the channel based on statistical or average channel information may be employed at the transmitter. In yet another embodiment, limited feedback from the receiver to the transmitter may be employed wherein a limited number of bits are sent from the receiver to the transmitter and employed in the selection of the constellation set P, the weighting matrix Wₜ, or appropriate parameters.

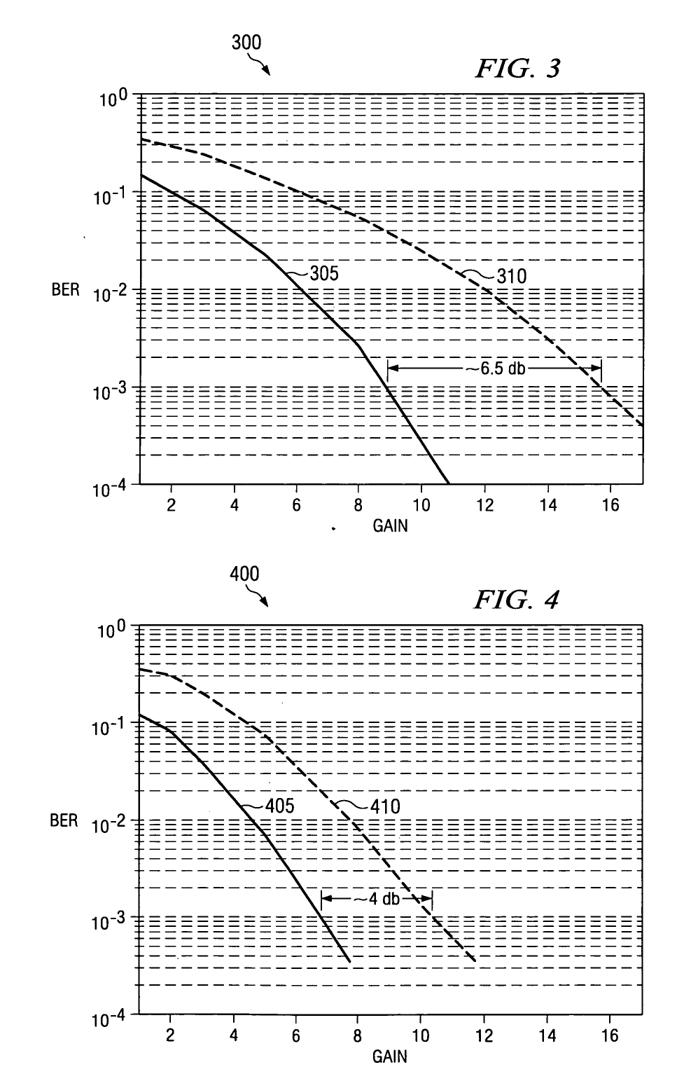

Turning now to FIG. 3, illustrated is a graph, generally designated 300, showing a bit error rate (BER) comparison between an embodiment of a constant rate waterpouring system and method constructed according to the principles of the present invention and V-BLAST, while employing a two by two MIMO communication system having Rayleigh fading. The graph 300 includes a first curve 305 representing a constant rate waterpouring coded BER, and a second curve 310 representing a V-BLAST coded BER.

The transmitted symbol vector was decoded using maximum likelihood decoding. The vector encoder/decoder was combined with a rate one-half outer convolutional code. The constant rate waterpouring communication system and method used a constellation set P={{64-QAM, 4-QAM}}. Thus, the constant rate waterpouring communication system and method always sent eight bits per transmission and sent six bits on the stronger transmit stream and two bits on the weaker transmit stream. This transmission was compared with a V-BLAST communication system sending 16-QAM symbols on each antenna. The first and second curves 305, 310 show approximately a 6.5 dB gain improvement in coded BER for the constant rate waterpouring system and method compared to V-BLAST at a BER of 10⁻³.

Turning now to FIG. 4, illustrated is a graph, generally designated 400, showing a bit error rate (BER) comparison between an embodiment of a constant rate waterpouring system and method constructed according to the principles of the present invention and V-BLAST, while employing a two by two MIMO communication system having equal energy Rayleigh fading paths. The graph 400 includes a first curve 405 representing a constant rate waterpouring coded BER and a second curve 410 representing a V-BLAST coded BER. The two by two MIMO communication system was operated as an OFDM system.

As discussed with respect to FIG. 3, the transmitted symbol vector was decoded using maximum likelihood decoding, and the vector encoder/decoder was combined with a rate one-half outer convolutional code. The constant rate waterpouring communication system and method used a constellation set P={{64-QAM, 4-QAM}}, and always sent eight bits per transmission with sent six bits being sent on the stronger stream and two bits on the weaker stream. This transmission was compared with a V-BLAST communication system sending 16-QAM symbols on each antenna. The first and second curves 405, 410 show approximately a 4 dB gain improvement in coded BER for the constant rate waterpouring system and method compared to V-BLAST for a BER of 10^{-3.}

In summary, the present invention introduces the broad concept of selecting combinations of constellations based on channel information and then applying those selected combinations to fixed numbers of bits. The present invention is not constrained to a single constellation as is V-BLAST, and is less computationally intensive than waterpouring techniques that seek to pour the maximum number of bits into each of the channels. Additionally, the invention sends the same number of bits during each transmission and allows for an adjustable complexity trade-off by changing the number of constellation combinations based on a performance requirement.

Although the present invention has been described in detail, those skilled in the art should understand that they can make various changes, substitutions and alterations herein without departing from the spirit and scope of the invention in its broadest form.

1. A waterpouring system for use with a multiple-input, multiple-output (MIMO) transmitter, comprising:
an encoding decision subsystem configured to select a constellation combination based on gains in channels of said MIMO transmitter;
a vector modulator subsystem, coupled to said encoding decision subsystem, configured to modulate a fixed number of bits in a bitstream with said constellation combination to generate a symbol vector; and
a normalization and precoding subsystem, coupled to said vector modulator subsystem, configured to weight said symbol vector based on said gains to yield a weighted symbol vector and distribute said weighted symbol vector among said channels.

2. The waterpouring system as recited in claim 1 wherein said encoding decision subsystem is configured to select said constellation combination from a set of constellation combinations constituted from at least one modulation technique selected from the group consisting of:
quadrature amplitude modulation, and
phase shift keying.

3. The waterpouring system as recited in claim 1 wherein said gains are configured to be reflected in an ordered, real diagonal matrix.

4. The waterpouring system as recited in claim 1 wherein said encoding decision subsystem is configured to select a maximum-rate subchannel constellation and a corresponding gain that encodes a number of bits based on a transmission capacity.

5. The waterpouring system as recited in claim 1 wherein said weighted symbol vector is configured to have an energy equaling a total transmit energy of said MIMO transmitter.

6. The waterpouring system as recited in claim 1 wherein said normalization and precoding subsystem is configured to distribute said weighted symbol vector along an orthogonal right singular vector of a matrix representing said channels.

7. The waterpouring system as recited in claim 1 wherein said MIMO transmitter is configured to form a part of a selected one of:
a narrowband wireless communication system employing multiple antennas,
a broadband communication system employing orthogonal frequency division multiplexing,
a time division multiple access communication system, and
a multiuser communication system.

8. A waterpouring method for a multiple-input, multiple-output (MIMO) transmitter, comprising:
selecting a constellation combination based on gains in channels of said MIMO transmitter;
modulating a fixed number of bits in a bitstream with said constellation combination to generate a symbol vector;
weighting said symbol vector based on said gains to yield a weighted symbol vector, and
distributing said weighted symbol vector among said channels.

9. The method as recited in claim 8 wherein said selecting comprises selecting said constellation combination from a set of constellation combinations constituted from at least one modulation technique selected from the group consisting of:
quadrature amplitude modulation, and
phase shift keying.

10. The method as recited in claim 8 wherein said gains are reflected in an ordered, real diagonal matrix.

11. The method as recited in claim 8 wherein said selecting comprises selecting a maximum-rate subchannel constellation and a corresponding gain that encodes a number of bits based on a transmission capacity.

12. The method as recited in claim 8 wherein said weighted symbol vector has an energy equaling a total transmit energy of said MIMO transmitter.

13. The method as recited in claim 8 wherein said distributing comprises distributing said weighted symbol vector along an orthogonal right singular vector of a matrix representing said channels.

14. The method as recited in claim 8 wherein said MIMO transmitter forms a part of a selected one of:
a narrowband wireless communication system employing multiple antennas,
a broadband communication system employing orthogonal frequency division multiplexing,
a time division multiple access communication system, and
a multiuser communication system.

15. A multiple-input, multiple-output (MIMO) transmitter employing an input bitstream, comprising:
a plurality of transmit channels; and
a waterpouring system, including:
an encoding decision subsystem that selects a constellation combination based on gains in said transmit channels,
a vector modulator subsystem, coupled to said encoding decision subsystem, that modulates a fixed number of bits in said input bitstream with said constellation combination to generate a symbol vector, and
a normalization and preceding subsystem, coupled to said vector modulator subsystem, that weights said symbol vector based on said gains to yield a weighted symbol vector and distributes said weighted symbol vector among said transmit channels.

16. The MIMO transmitter as recited in claim 15 wherein said encoding decision subsystem selects said constellation combination from a set of constellation combinations constituted from at least one modulation technique selected from the group consisting of:
quadrature amplitude modulation, and
phase shift keying.

17. The MIMO transmitter as recited in claim 15 wherein said gains are reflected in an ordered, real diagonal matrix.

18. The MIMO transmitter as recited in claim 15 wherein said encoding decision subsystem selects a maximum-rate subchannel constellation and a corresponding gain that encodes a number of bits based on a transmission capacity.

19. The MIMO transmitter as recited in claim 15 wherein said weighted symbol vector has an energy equaling a total transmit energy of said MIMO transmitter.

20. The MIMO transmitter as recited in claim 15 wherein said normalization and preceding subsystem distributes said weighted symbol vector along an orthogonal right singular vector of a matrix representing said transmit channels.
